(19) United States
(12) Patent Application Publication
(10) Pub. No.: US 2006/0071832 A1
(43) Pub. Date: Apr. 6, 2006

(54) Instantaneous phase digitizer

(76) Inventor: Zvi Regev, West Hills, CA (US)

Correspondence Address: ZVI REGEV, 24217 HIGHLANDER RD., WEST HILLS, CA, 91307, US

(21) Appl. No.: 10/696,409

(22) Filed: Oct. 28, 2003

Related U.S. Application Data
(60) Provisional application No. 60/421,856, filed on Oct. 29, 2002.

(51) Int. Cl. H03M 3/00

(52) U.S. Cl. 341/143

(57) ABSTRACT

The present invention provides a new and efficient way of measuring the instantaneous phase of periodic signals. The instantaneous phase information is also applicable to new methods of instantaneous frequency measurements, and signal frequency restoration.

### FIELD OF THE INVENTION

The present invention relates generally to analog to digital conversion, and more particularly to the measurement of signal phase.

### BACKGROUND OF THE INVENTION

Phase and frequency properties of signals are usually extracted from sampled analog signals, using Digital Signal Processing (DSP) methods. Typically in such applications, an Analog to Digital Converters (ADC), is employed to sample, measure, and digitize the instantaneous magnitude of the analog signal. A Digital Signal Processor is then used to extract the desired phase and frequency properties of the sampled signal.

Analog to digital converters use different methods to quantify and measure the magnitude of the sampled analog signal. In most of these methods, n sub-reference voltages are derived from a known reference voltage by dividing it using a network of resistors, wherein the smallest division of the reference voltage, defines the converter's resolution, or the magnitude of its Least Significant Bit (LSB). The magnitude of the sampled analog signal, is compared with all n sub-reference voltages, to determine the magnitude of the sampled analog signal. Based on the comparison with the n sub-references, the converter generates a digital code, describing the instantaneous magnitude of sampled analog signal.

FIG. 1A, shows a typical analog to digital converter, known in the art as “flash” converter, wherein a resistive network is used to divide a voltage reference into n sub-references, and the sampled analog signal is compared with these sub-references, to determine the magnitude of the sampled analog signal. In this digitizer, n analog magnitude comparators are used to compare each sub-reference voltage, with the analog signal. In every comparator the magnitude of the sampled analog input signal, is compared with the voltage of one sub-reference. In all the comparators wherein the magnitude of the analog signal is greater than that of the sub-reference voltage to which the analog signal is compared, the digital outputs of the comparators assume the logic value of “1”, and wherein all other comparators the outputs assume the logic value of “0”.

An alternative embodiment of an Analog to Digital Converter, shown in FIG. 1B. In this embodiment, resistor voltage dividers are used to divide the analog signal to be measured, into n different voltages, such that a first voltage is Vin/n, the second voltage is 2 Vin/n, the third is 3 Vin/n, etc. Each of the n comparators in the ADC compares one such voltage to a fixed voltage reference. The outputs of the comparators are similar to the outputs of the comparators used in the embodiment shown in FIG. 1A, wherein the outputs of comparators wherein the magnitude of the divided input voltage is greater than the reference voltage assume a logic level of “1”, and wherein the outputs of all other comparators assume the logic value of “0”.

The outputs of the comparators in both cases shown in FIGS. 1A, and 1B, are similar in function to the rise of the mercury in a thermometer, wherein in the array of comparators, all the comparators' outputs starting from one end of the array, all the way to a certain point in the array, assume the level of “1”, and wherein all the comparators' outputs from that point, all the way to the other end of the array, assume the level of “0”. Various methods are employed to convert the “thermometer” like outputs of the array of comparators, into a digital form comprised of log₂ₙ bits. These methods include combinations of logical functions, as well as simple lookup tables. Neither of these methods is the concern of this patent.

To extract phase and frequency properties of an analog signal, it must be treated as a complex signal, which can be described by its quadrature components. These quadrature components which have a relative phase difference of 90°, are obtained in various ways which depend on the application. In radio receivers, special mixers are employed, which generate two quadrature components. In alternative methods, a quadrature power spliter, also known in the art as a Hybrid Couplers, or even a network of resistors and capacitors, is used to generate the quadrature samples of a signal. To deal with complex signals, two ADCs are used, each to sample one of the two quadrature signal component. The resulting binary codes are than applied to a DSP processor, which views the two binary codes as referring to one complex signal, and using complex arithmetic, extracts the desired properties of the sampled signal.

This invention describes a method and an apparatus for direct extraction of the instantaneous phase of the sampled signal, without reverting to ADCs and DSPs.

In prior art analog to digital converter embodiment shown in FIG. 1B, the incoming analog signal Vin, is used as a base, from which n signals are derived. Of these n signals, the first signal is Vin/n, the second signal is 2 Vin/n, the third signal is 3 Vin/n, etc. These signals are applied to n comparators, which are used to compare the n signal's amplitudes, to one fixed voltage reference.

In the instantaneous phase digitizer, two quadrature inputs, I, and Q, are used. Both signals are of the same frequency and magnitude, and spaced 90° from each other. From these two quadrature signals, n sinewaves are derived, each one of a different phase, with respect to the input signal.

The quadrature input signals are I(t)=Aᵢ sin 2ΠFt, and Q(t)=A_{q} cos 2ΠFt, respectively. As A_{l=A}_{q}=1, they may be disregarded. These two quadrature signals may be combined in pairs to generate signals of any phase as shown in FIG. 5. Combining different magnitudes a, and b, of the quadrature signals, results in new sinewave signals having the properties:

$${φ}_{n} = arctan \frac{a}{b} , and M = \sqrt{{a}^{2} +} {b}^{2} ,$$

wherein φₙ is the phase of the new signal with respect to I and Q, and M is the amplitude of the new signal. Following this method, I and Q, are resolved into a set of n sinewaves, separated from adjacent signals by a phase shift of

$$Δ φ = \frac{Π}{n} ,$$

in radians. By comparing the resolved signals with zero crossing comparators, as shown in FIG. 3A, the instantaneous phase of the input signal can be determined to within Π/n radians. FIGS. 3B, and 6, show alternative resistors networks to generate the phase-shifted sinewaves. In the circuits described in FIGS. 3B, and 6, the comparators compare the relative magnitude of two phase shifted sinewaves, instead of when the sinewave cross the amplitude value of 0 volts. In either case, the comparators yield the same outputs patterns shown on FIG. 7.

The outputs of the comparators are sampled by the sampling clock, in an array of flip-flops, that follows the comparators. This clock thus becomes the time reference to which the phase of the input signal is related. The outputs of the sampling flip-flops combined generate a pattern, which is unique to each phase of the input signal. As can be seen in FIG. 7, showing a case of 8 comparators (n=8), 16 unique patterns are generated, each representing a different phase between 0°, and 360°, wherein the phase resolution obtainable is 180°/n.

The patterns at the outputs of the flip-flops must be converted into a digital code that assigns a numerical value for each pattern. As shown in FIG. 7, the outputs of 8 comparators yield 16 different patterns. Therefore, for n comparators the number of possible patterns is 2n, and the number of bits in a digital code required for the numerical presentation of 2n patterns is B=log₂2n. The conversion of the patterns at the outputs of the flip-flops into a digital code, usually a binary code, can be implemented in several ways. In this invention this conversion is done in a two steps process, in which the pattern is first converted into a Grey code, and then the Grey code is converted into a binary code. The two steps approach, for code conversion in the embodiment described here, is chosen because of its simplicity, as it only requires a few EXOR gates, as shown in FIGS. 8, and 11. EXOR gates can be implemented in semi-dynamic CMOS circuits as shown in FIGS. 9, and 10.

A block diagram of an instantaneous phase digitizer is shown in FIG. 2.

The typical input signal to the digitizer may be complex, comprised of any number of various frequency components, in the form G_{ω=a}₀ω₀+a₁ω₁+ . . . aₙωₙ. To measure the phase of the input signal it is important to eliminate all the higher frequency components of the signal, except of the fundamental which is the lowest frequency component, before any further processing of the incoming analog signal. It is also important to eliminate any influence of the input signal's amplitude on the phase measurements, and to guarantee that only a fixed amplitude signal is processed by the digitizer.

To guarantee the required conditions for the input signal, the input signal is amplified, and then hard limited to form a rectangular waveform, which has a fixed amplitude. The rectangular waveform signal has a frequency domain spectrum consisting of the fundamental frequency, and odd and even harmonics of the fundamental frequency. It is required that all the harmonics other than the fundamental must be eliminated. The output of the limiter is buffered, and then applied to a low-pass filter to block and remove all higher harmonics in the spectrum of the limited signal, leaving only the fundamental frequency to pass the filter. Since the second harmonic is closest in frequency to the fundamental, and must be eliminated for proper operation of the digitizer, the low-pass filter is designed such that its cut-off frequency is just below the frequency of the second harmonic of the lowest fundamental frequency to be used. This low-pass filter therefore defines the operational bandwidth of the digitizer to be just under one octave, with respect to the lowest fundamental frequency.

To obtain two signals I, and Q, such that these signal will have a quadrature phase relationship to each other, a quadrature power divide follows the filter. The outputs of the quadrature power divider are two signals, which are phase shifted by 90 degrees with respect to each other, and are termed I (for Incident), and Q (for quadrature). There are several methods known in the art, for obtaining quadrature power division. The simplest form consists of two resistors and two capacitors connected as RC, and CR combinations, as shown in FIG. 2.

To comply with the Nyquist requirements, the sampling clock frequency is more that than twice the highest frequency that can pass the low-pass filter.

This invention describes a method and apparatus to measure the instantaneous phase of a signal. Measuring the instantaneous phase of the signal twice with a known time difference between the two measurements, allows the measuring of the instantaneous frequency of the signal using:

$$F = \frac{{Phase}_{2} - {Phase}_{1}}{Δ Time} ,$$

wherein Phase1, and Phase2 are the instantaneous phases measured, and ΔTime is the time length between the two phase measurements.

FIG. 12, shows an embodiment of an Instantaneous Frequency Measurement (IFM) circuit, comprising an instantaneous phase digitizer, a register and a subtractor. On every clock transition, the digitizer outputs the instantaneous phase measured on that clock transition. The digitizer's output is applied to the subtractor, and on a subsequent clock transition that data is also stored in the register. By the time the register is loaded with the previous data, the digitizer outputs the present instantaneous phase. The two inputs to the subtractor thus receive the present instantaneous phase, and the previous one, and the output of the subtractor is the instantaneous phase difference of the input signal over one clock period. As the clock period is fixed and known, the instantaneous frequency is derived, by dividing the instantaneous phase difference by the clock period time.

In another application, in the field of electronic warfare, special memories are used to capture RF RADAR signal and store them for subsequent use in counter measures. In such memories known in the art as Digital RF Memories (DRFM), the phase of RF signals is digitized, and stored in the memory. When recalled from the memory, the phase of the stored signal is restored to a sinewave, and transmitted out of the system.

In prior art DRFM, input signals are converted into a rectangular shaped signal. Using such signals the phase resolution of the stored data is limited the phase difference between two transitions of the rectangular shaped signal, typically about 180°.

Using the direct phase digitizer in the DRFM, as shown in FIG. 13, allows for a fine phase resolution, and a spectrally cleaner output signal.

In yet another application, short bursts of signals are available, wherein it is desirable to generate a continuous periodic signal at the exact frequency of the signal in the short burst.

In prior art embodiments, phase locked loop type oscillators are employed, to lock on the frequency of the signal in the short burst. This type of embodiment has severe limitations as phase locked loops require significant time to lock on a signal, and frequency generated by the loop has a tendency to drift away without repeated corrections.

In the embodiment shown in FIG. 14, an instantaneous phase digitizer measures the instantaneous phase of the input signal, repeatedly, on every clock transition, during the short burst. A subtractor an a register following the digitizer generate the instantaneous phase difference on every clock transition. An averager that follows the subtractor generates the average phase difference during the burst. The output of the averager is stored in a following register. On every clock transition, the adder adds the content of the register, to the previous sum at the output of the adder. As a result, on every clock transition, the sum at the output of the adder increases by the average phase difference. This constant amount of phase change over a known period of time, constitutes a fixed frequency, exactly at the frequency of the signal in the short burst. A sine lookup table followed by a digital to analog converter, are used to convert the digital output of the adder, to a spectrally clean sinewave.

### A BRIEF DESCRIPTION OF THE DRAWINGS

FIG. 1A, shows a prior art magnitude quantizer.

FIG. 1B, shows an alternative prior art magnitude quantizer.

FIG. 2, shows an embodiment of the direct phase digitizer.

FIG. 3A, shows an embodiment of a phase quantizer.

FIG. 3B, shows another embodiment of a phase quantizer.

FIG. 4, shows a phasor presentation of complex signals.

FIG. 5, shows a set of phase-shifted sinewaves.

FIG. 6 shows an alternative embodiment of a phase quantizer.

FIG. 7, shows waveforms at the inputs to the flip-flops.

FIG. 8, shows a method of converting the outputs of the flip-flops into a digital code.

FIG. 9, shows an embodiment of an EXOR gate.

FIG. 10, shows an embodiment of an EXOR and an AND combined.

FIG. 11, shows the conversion of Gray code to Binary code.

FIG. 12, shows an embodiment of an Instantaneous Frequency Measurement device.

FIG. 13, shows an embodiment of a Digital RF Memory system.

FIG. 14, shows an embodiment of a Frequency Restoration circuit.

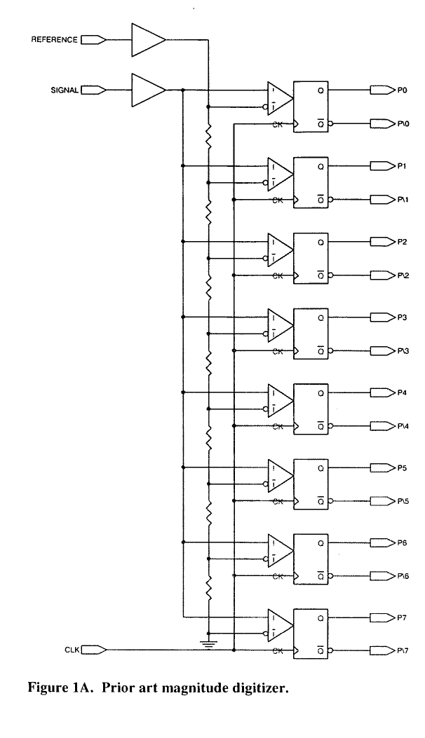

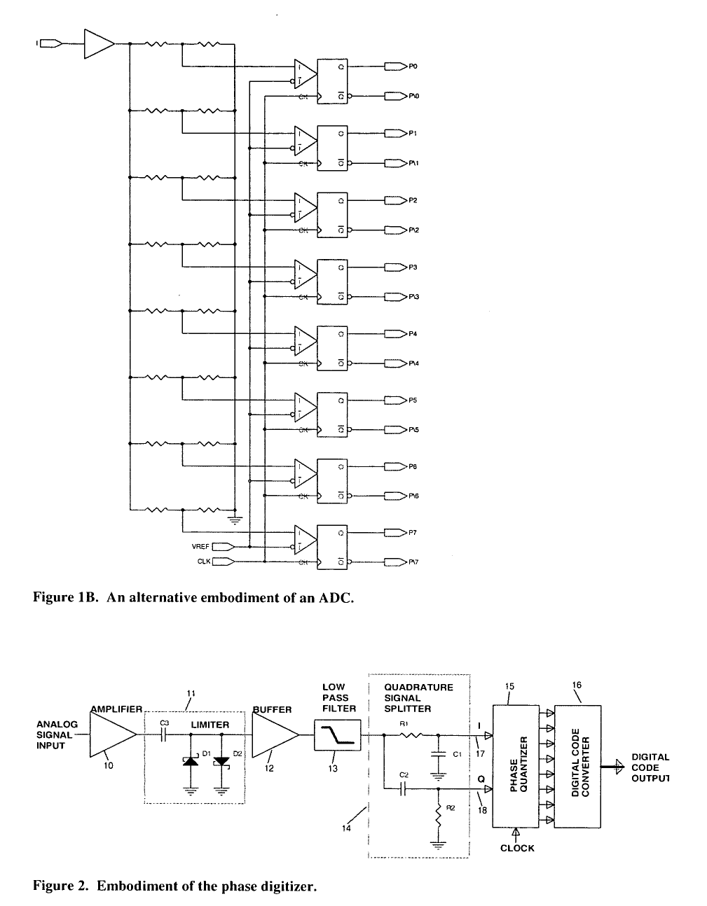

### A DESCRIPTION OF THE INVENTION

In the embodiment shown in FIG. 2, the input signal, is amplified by the high gain amplifier (10), and then applied to a limiter (11), which in this embodiment is comprised of two Schottky diodes (D1, D2). As a result, the combination of the amplifier followed by the limiter produces a nearly ideal rectangular waveform.

The limiter is followed by a buffer (12), and than a low-pass filter (13). The filter (13) defines the operational frequency range of the digitizer, and It is designed such that its cutoff frequency F_{co} is lower than half the sampling clock frequency F_{ck}.

The filter is followed by a quadrature signal splitter (14), comprised of resistors R1, R2, and capacitors C1, C2, wherein R1=R2=R, and C1=C2=C. The values of R and C, are selected such that at the frequency in the middle of the operational band of the digitizer, F_{mid}=F_{co}/2, R=2ΠF_{mid}C. As a result, the phases of the signal coming out of the splitter are shifted. By the combination of R1, and C1, the signal is shifted −45°, and by the combination of C2 and R2, the signal is shifted +45°. The phase difference between the two outputs I (17), and Q (18), is thus 90°. The two quadrature outputs are applied to the phase quantizer.

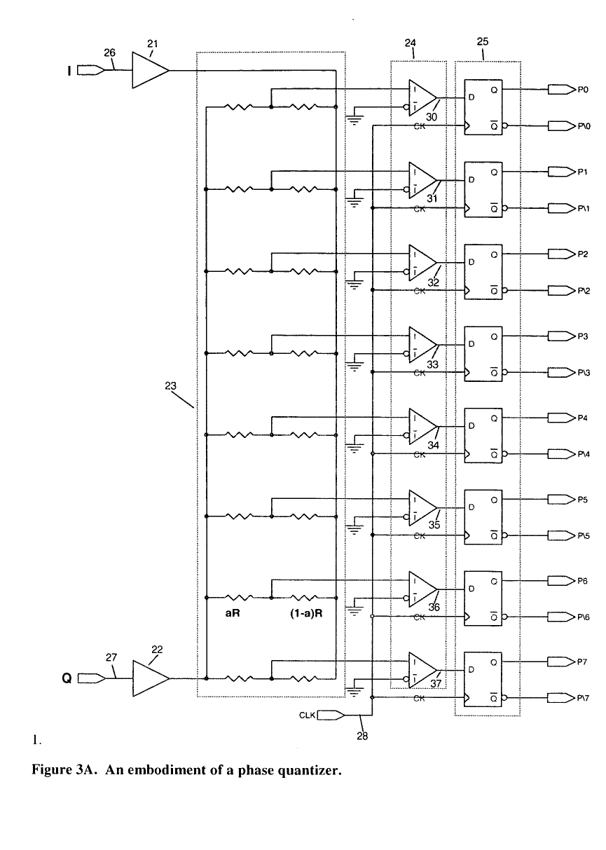

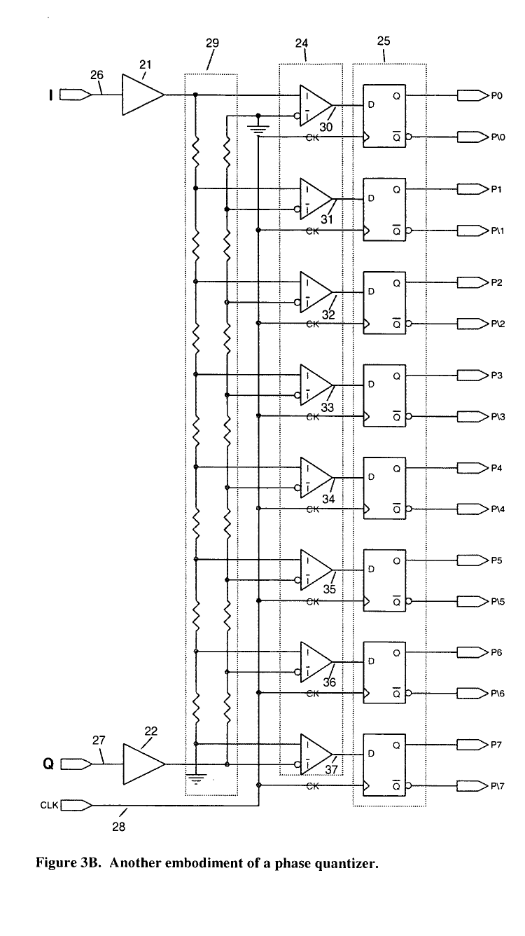

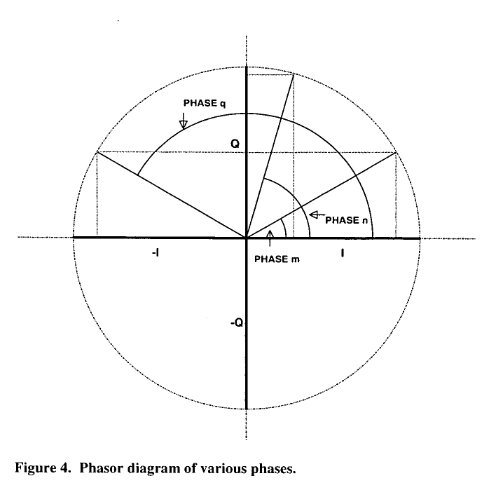

Two embodiments of the quantizer is shown in FIGS. 3A, and 3B. In either quantizer, two inputs, I (2ˆ), and Q (27), are buffered by the buffers (21), and (22), respectively. The outputs of the buffers (21, 22) are connected to a resistive network ((23) in FIG. 3A, and (29) in FIG. 3B). In FIG. 3A, the resistive network (23) is comprised of n pairs of resistors, wherein the total series resistance in each pair is R, and wherein one resistor of the pair has a resistance of aₖR, and the other resistor in the pair has the resistance of (1−aₖ)R, and wherein aₖ is the scaling factor assigned to each pair of resistors. The value of aₖ ranges from 0 to 1, and is unique to the (k)th location in the resistive array. As a result, the voltage generated by each pair of resistors, and applied to the input of comparator, is Vₖ=Vᵢa sin 2ΠF+V_{q}(1−a)cos 2ΠF, which is a sinusoidal waveform, phase shifted by

$$Δ {φ}_{k} = arctan \frac{{a}_{k}}{1 - {a}_{k}} .$$

In the resistive network (29), in FIG. 3B, the I, and Q signals are applied each to a chain or resistors, wherein all the resistors in the chain are of the same value R. The resistor chains divide the magnitude of the I, and Q input signals, such that the signals at the inputs to each comparator are

$${V}_{ki} = \frac{n - k}{n} {V}_{i} sin 2 Π F , and {V}_{kq} = \frac{k}{n} {V}_{q} cos 2 Π F .$$

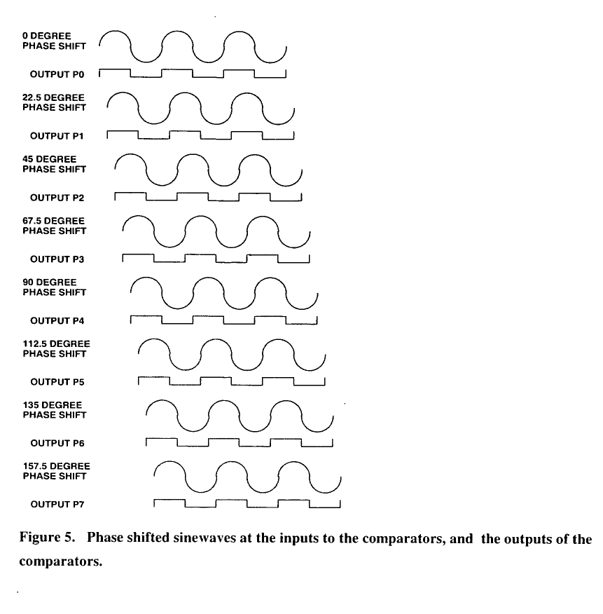

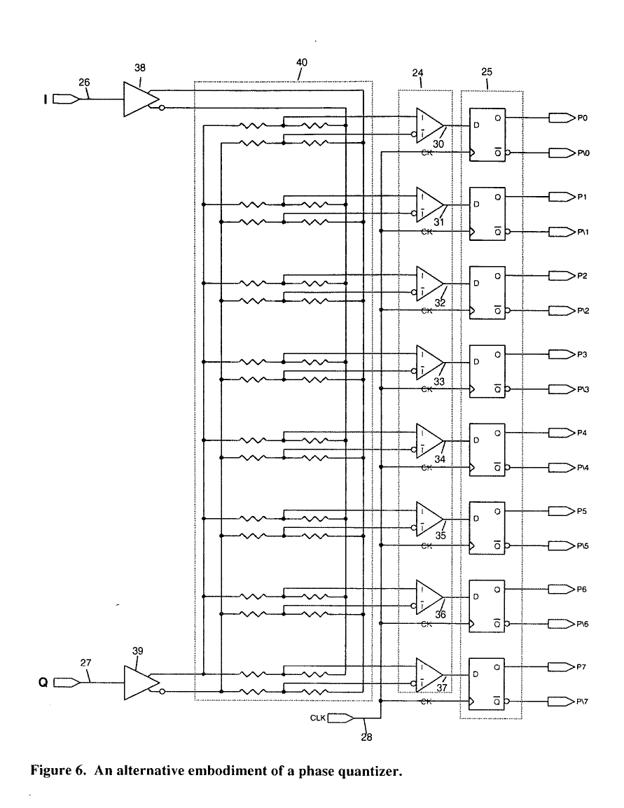

In this configuration each comparator compare the difference in magnitude between Vₖᵢ and V_{kq}. In the digitizer embodiment shown in FIG. 6, the resistors network has been modified to combine the relative advantages of the resistors networks shown in FIGS. 3A, and 3B. FIG. 5, shows an example of signals at the inputs to the comparators shown in FIG. 3A, for a case wherein n, the number of comparators is 8.

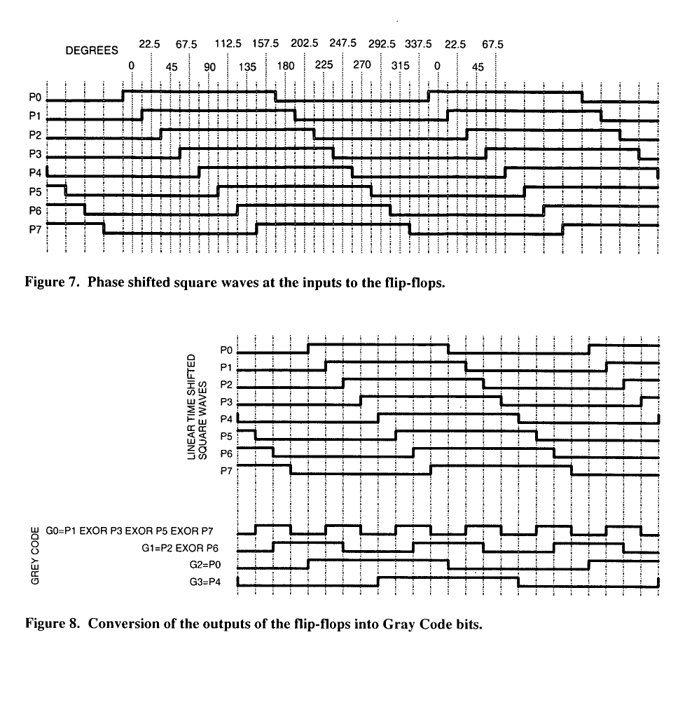

In the quantizer, the inputs of n comparators (24), are connected to the resistive networks. The output of each of the n comparator (24) connects to one of the n flip-flops (25). The signal patterns at the outputs of the comparators are shown in FIG. 7. These pattern show an example where n=8. For the case wherein n=8, the possible phase resolution is 180°/8=22.5°. As can be seen in FIG. 7, the patterns generated provide 16 distinguished patterns, one for each measurable phase, in 22.5° increments. The flip-flops (25), which follow the comparators, sample the outputs of the comparators on the instance of the transition of the sampling clock (28). The sampled patterns then appear at the outputs of the flip-flops (25), and remain unchanged for the duration of one clock period, during which these patterns are converted into a desirable digital code.

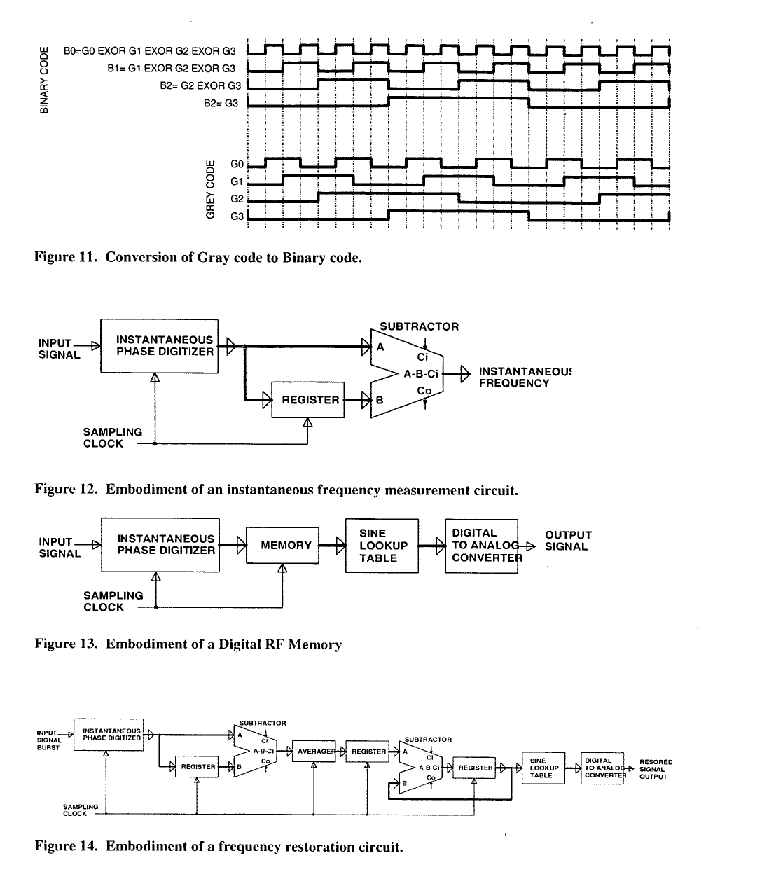

Referring to FIG. 2, the outputs of the digitizer (15) connect to a digital code converter (16), which converts the patterns at the outputs of the digitizer into a digital code. The conversion of the patterns at the outputs of the flip-flops is accomplished in two stages, using ExclusiveOR (EXOR) gates. In the first stage, the patterns are converted into a Grey code. This conversion can be best explained using the sample patterns generated by 8 comparators. As these patterns provide 16 unique patterns, a digital code would require 4 bits to identify all 16 cases. In this example, the least significant Grey code bit G0, is the EXOR function of all the odd patterns combined as: G0=P1⊕P3⊕P5⊕P7. The next Grey code bit is G1=P2⊕P6, the next bit is G2=P0, and the most significant bit is G3=P, as shown in FIG. 8. In the second stage of the code conversion, the Grey code is converted into a Binary code, again using EXOR gates. In this conversion, the Binary LSB is B0=G0⊕G1⊕G2⊕G3, the next bit is B1=G0⊕G1⊕G2, the next bit is B2=G0⊕G1, and the MSB is B3=G3, as shown in FIG. 11.

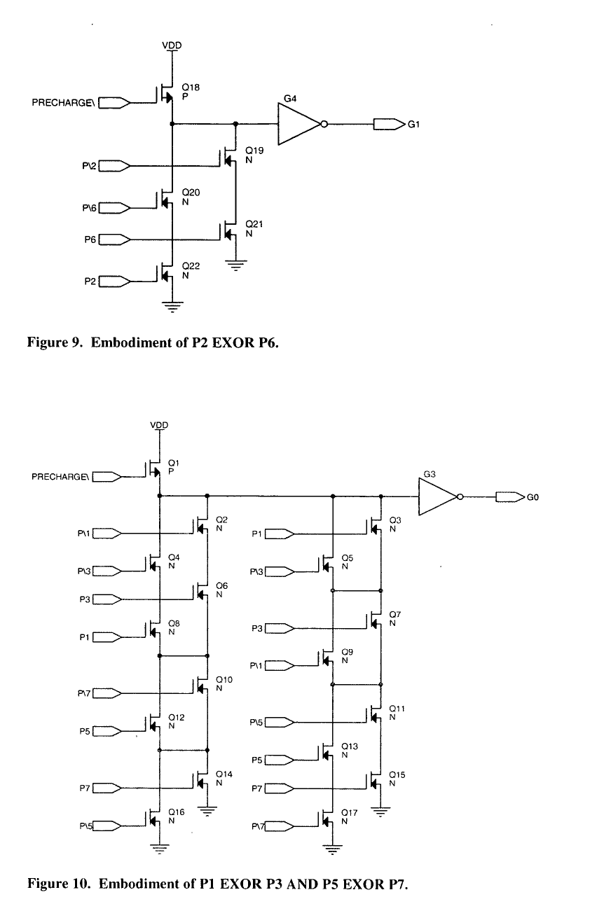

The use of EXOR gates for the conversion process is very convenient as the construction of EXOR gates in integrated circuits is rather simple, especially when dynamic methods are used. FIG. 9, shows a two inputs dynamic EXOR gate. In terms of current flow, an OR gate is constructed by connecting two switches in parallel, and an AND gate is constructed by connecting two switches in series. Using Boolean arithmetic, A EXOR B=A\B+AB\. In FIG. 9, the transistors Q20, and Q22, form one AND function, and the transistors Q19, and Q21, form another AND function. Connecting the two AND functions in parallel form the OR function between the two AND functions. FIG. 10, shows an EXOR gate with 4 inputs.

What is claimed as new and desired to be protected by Letters Patent of the United States is:

1. A method of obtaining the instantaneous phase of a sinusoidal periodical signal, comprising:
generating a plurality of phase shifted replicas of the sinusoidal signal;
converting the phase shifted sinusoidal signals into time delayed square shaped signals;
comparing the transition times of the square shaped signals with the transition time of a reference clock;
determining which transitions of the square shaped signals occurs before and after the transition of the reference clock;
converting the resulting information into a digital code.

2. A method as in claim 1, wherein the plurality of phase shifted replicas of the sinusoidal signal comprises of n sinusoidal signals phase shifted with regards to each other by the amount of 180°/n.

3. A method as in claim 1, wherein the conversion of the plurality of phase shifted sinusoidal signals into square shaped signals is executed using hard limiting electronic devices or high gain amplifiers or digital comparators.

4. A method as in claim 1, wherein the determination of the timing of transitions in the square shaped signals is done using a flip-flop or a sampling device.

5. A method as in claim 1, wherein the conversion of the output of the flip-flops or sampling devices into a digital code is obtained using EXOR functions.

6. A method as in claim 1, wherein the digital code resulting from the code conversion may be a Gray code or a binary code.

7. An apparatus to determine the instantaneous phase of two sinusoidal signal in quadrature, comprising:
Two input buffers one for each of the quadrature related sinusoidal signals;
Two resistive networks each comprised of n−1 resistors having n taps;
An array of n comparators each having two differential inputs wherein one input connects to one tap on one resistive network and wherein the other input connects to one tap on the other resistive network;
An array of n flip-flops each having an input connecting to one output of a comparator and wherein a reference clock connects to all the flip-flops;
An array of Exclusive OR gates connecting to the outputs of the flip-flops to generate a digital code

8. An apparatus as in claim 7, wherein one end of each resistive network connects to the output of one input buffer and wherein the other end of that resistive network connects to ground.

9. An apparatus as in claim 7, wherein n taps on each resistive network include the output of the input buffer and ground.

10. An apparatus as in claim 7, wherein the digital output code is a Gary code.

11. An apparatus as in claim 7, wherein the digital output code is a Binary code.

12. An apparatus to determine the instantaneous phase of a complex signal, comprising:
An input amplifier;
A hard limiting device;
A buffer;
A low-pass filter;
A quadrature signal divider;
Two input buffers one for each of the quadrature related sinusoidal signals;
Two resistive networks each comprised of n−1 resistors having n taps;
An array of n comparators each having two differential inputs wherein one input connects to one tap on one resistive network and wherein the other input connects to one tap on the other resistive network;
An array of n flip-flops each having an input connecting to one output of a comparator and wherein a reference clock connects to all the flip-flops;
An array of Exclusive OR gates connecting to the outputs of the flip-flops to generate a digital code

13. An apparatus as in claim 12, wherein the digital output code is obtained in a two step sequence utilizing EXOR functions.

14. An apparatus as in claim 12, wherein a hard limiter comprises limiting diodes or high gain saturated amplifiers.

15. An apparatus as in claim 12, wherein the frequency range of operation is defined by the low-pass filter.

16. An apparatus as in claim 12, wherein a quadrature signal divider comprises a hybrid coupler or an RC/CR phase shifting network.

17. An apparatus to determine the instantaneous phase of two sinusoidal signal in quadrature, comprising:
Two input buffers one for each of the quadrature related sinusoidal signals wherein each buffer comprises two differentially complementary linear outputs;
An array of n comparators each having two differential inputs wherein each input connects to two resistors and wherein one said resistors connects to one output of one buffer and the second said resistor connects to one output of the second input buffer;
An array of n flip-flops each having an input connecting to one output of a comparator and wherein a reference clock connects to all the flip-flops;
An array of Exclusive OR gates connecting to the outputs of the flip-flops to generate a digital code

18. An apparatus as in claim 17, wherein the digital output code is a Gary code.

19. An apparatus as in claim 17, wherein the digital output code is a Binary code

20. An apparatus as in claim 17, wherein the digital output code is obtained in a two step sequence utilizing EXOR functions.

21. An apparatus to determine the instantaneous phase of a complex signal, comprising:
An input amplifier;
A hard limiting device;
A buffer;
A low-pass filter;
A quadrature signal divider;
Two input buffers one for each of the quadrature related sinusoidal signals wherein each buffer comprises two differentially complementary linear outputs;
An array of n comparators each having two differential inputs wherein each input connects to two resistors and wherein one said resistors connects to one output of one buffer and the second said resistor connects to one output of the second input buffer;
An array of n flip-flops each having an input connecting to one output of a comparator and wherein a reference clock connects to all the flip-flops;
An array of Exclusive OR gates connecting to the outputs of the flip-flops to generate a digital code

22. An apparatus as in claim 21, wherein the digital output code is a Gary code.

23. An apparatus as in claim 21, wherein the digital output code is a Binary code

24. An apparatus as in claim 21, wherein the digital output code is obtained in a two step sequence utilizing EXOR functions.

25. An apparatus to determine the instantaneous phase of a complex signal utilized in an instantaneous frequency measurement apparatus.

26. An apparatus to determine the instantaneous phase of a complex signal utilized in digital RF memories.

27. An apparatus to determine the instantaneous phase of a complex signal utilized in signal restoration circuits.
